(19) United States
(12) Patent Application Publication
(10) Pub. No.: US 2008/0129282 A1
(43) Pub. Date: Jun. 5, 2008

(54) Method and Apparatus for Magnetic Field Sensor Calibration

(75) Inventor: Michael Lemp, Rancho Santa Margarita, CA (US)

Correspondence Address: CROCKETT & CROCKETT, 24012 CALLE DE LA PLATA, SUITE 400, LAGUNA HILLS, CA, 92653, US

(73) Assignee: Yamcon, Inc.

(21) Appl. No.: 11/849,917

(22) Filed: Sep. 4, 2007

Related U.S. Application Data
(63) Continuation of application No. 11/607,293, filed on Nov. 30, 2006.

(51) Int. Cl. G01R 35/00

(52) U.S. Cl. 324/202

(57) ABSTRACT

The methods and devices provide for calibration of two or three-axis magnetic field sensors with an artificial magnetic calibration field, or a sequence of magnetic calibration fields, that overwhelm the earth's magnetic field and any other extraneous magnetic fields that may be present in the calibration area. The calibration field or fields are produced with a known relationship to a test stand or jig on which a two and or three-axis magnetic field sensor is secured. The calibration fields are oriented to produce fields that have generally parallel lines of force (relative to the sensor to be calibrated) with minimal curvature or discontinuity. For each coil or calibration field, data from each sensor may be collected and analyzed to enable one or more correction factors to be determined for each sensor. The correction factors may be provided to the apparatus in which the magnetic sensor is secured to correct sensor data and provide more accuracy.

### RELATED APPLICATIONS

This application claims priority from copending U.S. patent application Ser. No. 11/607,293 filed Nov. 30, 2006.

### FIELD OF THE INVENTIONS

The inventions described below relate to the field of magnetic sensor calibration, and more specifically to methods and apparatus for calibrating two-axis and or three-axis magnetic field sensors for use in celestial object locators.

### BACKGROUND OF THE INVENTIONS

Calibration of magnetic field sensors intended for detection of the magnetic field of the earth may be performed using the earth's magnetic field as a reference. However the presence of structural steel, electrical wiring and motors as in buildings and factories significantly disrupts the earth's magnetic field, and may generate additional magnetic fields and yield imprecise results.

What is needed are methods and apparatus for producing one or more stable and predictable magnetic fields that may be used to calibrate two and or three-axis magnetic field sensors.

### SUMMARY

The methods and devices described below provide for calibration of multi-axis sensors such as two or three-axis magnetic field sensors with an artificial magnetic calibration field, or a sequence of magnetic calibration fields, that overwhelm the earth's magnetic field and any other extraneous magnetic fields that may be present in the calibration area. The calibration field or fields are produced with a known relationship to the test stand or jig on which a two and or three-axis magnetic field sensor is secured. The calibration fields are oriented to produce fields that have generally parallel lines of force (relative to the sensor to be calibrated) with minimal curvature or discontinuity. For each coil or calibration field, data from each sensor may be collected and analyzed to enable one or more correction factors to be determined for each sensor. The correction factors may be provided to the apparatus in which the magnetic sensor is secured to correct sensor data and provide more accuracy.

In an alternative technique, a single magnetic field source may be used and the sensor jig may enable two or three degrees of freedom to orient the sensor jig and the sensor secured thereon in two or three orthogonal positions to perform the necessary calibration of the sensor. For example, the x-direction sensor may be calibrated with the sensor jig in a first position with the X-sensor oriented parallel to the calibration field. To calibrate the y-sensor the jig may be oriented 90° from the first position into a second position to place the y-sensor parallel to the calibration field. If a third sensor axis is available it may be calibrated by orienting the sensor jig 90° from both the first and second positions into a third position with the Z-axis sensor oriented parallel to the calibration field. At each position, data from each sensor may be collected and analyzed to enable one or more correction factors to be determined for each sensor. The correction factors may be provided to the apparatus in which the magnetic sensor is secured to correct sensor data and provide more accuracy.

### BRIEF DESCRIPTION OF THE DRAWINGS

FIG. 1 is a perspective view of a celestial object location device having magnetic field sensors interacting with the magnetic field of the earth.

FIG. 2 is a perspective view of a three-dimensional magnetic field sensor oriented relative to a viewing axis.

FIG. 3 is a perspective view of a three-dimensional magnetic field sensor in magnetic calibration fields.

### DETAILED DESCRIPTION OF THE INVENTIONS

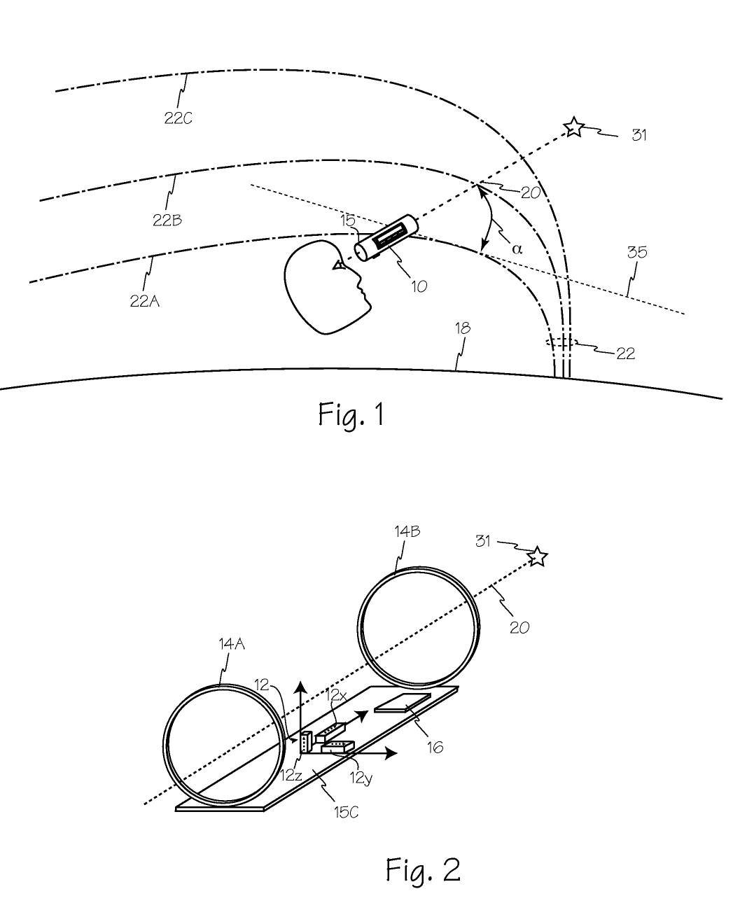

Celestial object locating device 10 of FIG. 1 includes electronics 15 oriented relative to viewing axis 20. A two or three-axis magnetic field sensor incorporated in electronics 15 may be used to determine one or more angles such as angle α relative to magnetic field 22 of earth 18. At most locations on the earth a user will encounter magnetic field lines of force such as lines 22A, 22B and 22C that are generally parallel.

Electronics 15 may include one or more subassemblies such as board 15C and microprocessor 16 of FIG. 2. Subassembly 15C may include a two or three-axis magnetic field sensor such as three-axis sensor 12. Sensor 12 includes three sub-elements 12X, 12Y and 12Z. The orientation of each sub-element to the other sub-elements and to the viewing axis may be calibrated and offset parameters determined for each sub-assembly.

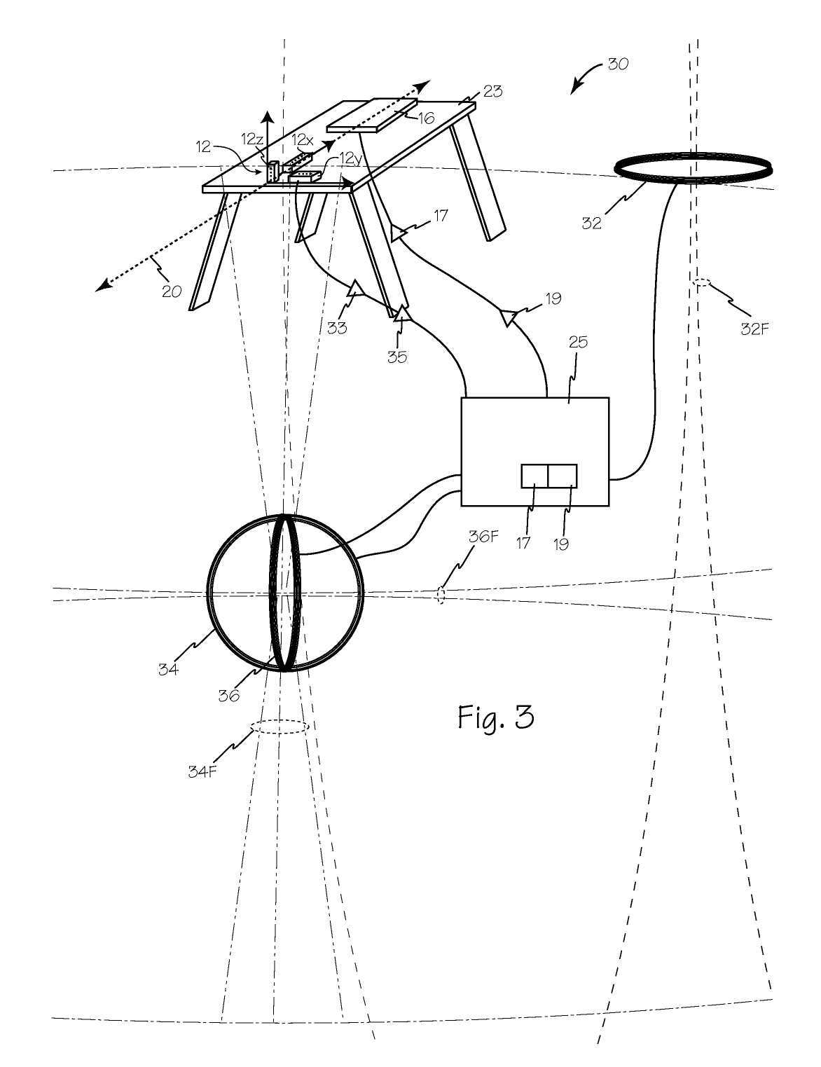

Calibration system 30 of FIG. 3 includes test stand 23 and field generators 32, 34 and 36 which generate magnetic calibration fields 32F, 34F and 36F respectively. Calibration system 30 is controlled by controller 25 which initiates the application of each magnetic calibration field and collects orientation data 33 from each sensor sub-element. Orientation data 33 is the output of each sensor sub-element that indicates the orientation of viewing axis 20 relative to the applied calibration field. Orientation data 33 may be used to determine correction factors 17 that may be applied to orientation data 33 to enable microprocessor 16 to correct orientation data 33 to accurately determine the real orientation of viewing axis 20 relative to the earth's magnetic field.

Controller 25 may also vary the intensity of each applied magnetic calibration field to collect field strength data 35. Field strength data 35 may be used by controller 25 to generate field strength correction factors 19 that may be used by microprocessor 16 to correct field strength data 35 to accurately determine the real orientation of viewing axis 29 relative to the earth's magnetic field.

While the preferred embodiments of the devices and methods have been described in reference to the environment in which they were developed, they are merely illustrative of the principles of the inventions. Other embodiments and configurations may be devised without departing from the spirit of the inventions and the scope of the appended claims.

We claim:

1. A method of calibrating a multi-axis magnetic sensor comprising the steps:
securing an electronic assembly including a multi-axis magnetic field sensor on a test stand;
energizing a first magnetic field generator to produce a first magnetic field at the test stand;
energizing a second magnetic field generator to produce a second magnetic field at the test stand, the second magnetic field orthogonal to the first magnetic field;
energizing a third magnetic field generator to produce a third magnetic field at the test stand, the third magnetic field orthogonal to the first and second magnetic fields;
controlling the first, second and third magnetic field generators and the electronic assembly with a controller;
monitoring the multi-axis magnetic field sensor with the controller and producing one or more correction factors to be provided to the electronic assembly.

2. The method of claim 1 wherein the electronic assembly including a multi-axis magnetic field sensor is a celestial object location device.

3. A device for calibration of a multi-axis magnetic sensor in an electronic assembly comprising:
a first magnetic field generator oriented to produce a first magnetic field at the multi-axis magnetic field sensor;
a second magnetic field generator oriented to produce a second magnetic field at the multi-axis magnetic field sensor, the second magnetic field orthogonal to the first magnetic field;
a third magnetic field generator oriented to produce a third magnetic field at the multi-axis magnetic field sensor, the third magnetic field orthogonal to the first and second magnetic fields;
a controller for controlling the first, second and third magnetic field generators and the electronic assembly, the controller monitoring the multi-axis magnetic field sensor and producing one or more correction factors to be provided to the electronic assembly.

4. the device of claim 3 wherein the electronic assembly is a celestial object location device.

5. A method of calibrating a multi-axis magnetic sensor comprising the steps:
securing an electronic assembly including a multi-axis magnetic field sensor on a test stand;
energizing a magnetic field generator to produce a first magnetic field at the test stand, the first magnetic field generally parallel to a first axis of the multi-axis magnetic sensor;
controlling the magnetic field generator and the electronic assembly with a controller;
monitoring the multi-axis magnetic field sensor with the controller and producing one or more first field correction factors;
orienting the magnetic field generator to produce a second magnetic field orthogonal to the first magnetic field;
energizing a magnetic field generator to produce a second magnetic field at the test stand, the second magnetic field generally parallel to a second axis of the multi-axis magnetic sensor and orthogonal to the first axis;
controlling the magnetic field generator and the electronic assembly with a controller;
monitoring the multi-axis magnetic field sensor with the controller and producing one or more second field correction factors;
orienting the magnetic field generator to produce a third magnetic field orthogonal to the first magnetic field and the second magnetic field;
energizing a magnetic field generator to produce a third magnetic field at the test stand, the third magnetic field generally parallel to a third axis of the multi-axis magnetic sensor and orthogonal to the first axis and the second axis;
controlling the magnetic field generator and the electronic assembly with a controller;
monitoring the multi-axis magnetic field sensor with the controller and producing one or more third field correction factors;
providing the first, second and third field correction factors to the electronic assembly.

6. The method of claim 5 wherein the electronic assembly including a multi-axis magnetic field sensor is a celestial object location device.

7. A device for calibration of a multi-axis magnetic sensor in an electronic assembly comprising:
a test stand for securing an electronic assembly including a multi-axis magnetic sensor;
a magnetic field generator for producing a magnetic field at the test stand;
means for orienting the electronic assembly to experience a first magnetic field, and reorienting the electronic assembly to experience a second magnetic field orthogonal to the first magnetic field, and reorienting the electronic assembly to experience a third magnetic field orthogonal to both the first and second magnetic fields;
a controller for controlling the magnetic field generator and the electronic assembly, the controller monitoring the multi-axis magnetic field sensor and producing one or more correction factors for each orientation of the electronic assembly to be provided to the electronic assembly.

8. The device of claim 7 wherein the electronic assembly is a celestial object location device.
